(19) United States
(12) Patent Application Publication
(10) Pub. No.: US 2010/0058142 A1
(43) Pub. Date: Mar. 4, 2010

(54) APPARATUS, METHODS, AND COMPUTER PROGRAM PRODUCTS UTILIZING A GENERALIZED TURBO PRINCIPLE

(75) Inventor: Lars Puggaard Bogild Christensen, Frederiksberg (DK)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/514,607

(22) PCT Filed: Nov. 15, 2007
(86) PCT No.: PCT/IB07/03506

§ 371 Date: Nov. 13, 2009

Related U.S. Application Data
(60) Provisional application No. 60/859,405, filed on Nov. 16, 2006.

(51) Int. Cl. H03M 13/05; G06F 11/10; G06F 11/07

(52) U.S. Cl. 714/752; 714/746; 714/E11.023; 714/E11.032

(57) ABSTRACT

Exemplary embodiments of the invention provide a generalized Turbo principle that enables the exchange of region beliefs between components. The generalized Turbo principle provides various advantages over the traditional Turbo principle such as, for example, a lower Bit Error Rate (BER) and/or a better quality of the end-result marginals. In one exemplary embodiment, a method includes: receiving an encoded signal (501); and decoding the received signal using a generalized Turbo principle wherein region beliefs are exchanged between components (502). In another exemplary embodiment, methods, computer programs and apparatus are presented for generating a graph structure for a system having a plurality of components. As a non-limiting example, the generated graph structure may be seen to correspond to the region graphs underlying the generalized Turbo principle.

### TECHNICAL FIELD

The teachings in accordance with the exemplary embodiments of this invention relate generally to systems in which the Turbo principle may be employed and, more specifically, relate to communication systems.

### BACKGROUND

In telecommunication systems, a transmission channel often causes interference to data transmission. Interference occurs in all systems, but in particular in wireless telecommunication systems the radio path attenuates and distorts the signal to be transmitted in a variety of ways. On the radio path, interference is typically caused by multipath propagation, various fades and reflections and also other signals transmitted on the same radio path.

To reduce the effects of interference various encoding methods have been developed, which aim to protect the signal from interference and which also aim to eliminate interference-induced errors in the signal. One widely used encoding method is convolutional coding. In the convolutional coding the signal to be transmitted, consisting of symbols, is encoded into code words which are based on the convolution of the original signal with code polynomials. The convolutional code is determined by the coding rate and the coding polynomials. The coding rate (k/n) refers to the number (n) of produced coded symbols in relation to the number (k) of symbols to be coded. The encoder is often implemented by means of shift registers. The constraint length K of the code often refers to the length of the shift register. The encoder can be considered a state machine having 2^{K-1} states. One encoding method further developed from the convolutional code is a parallel concatenated convolutional code (PCCC), which is also known as a Turbo code.

One suggestion for minimizing the effects of multipath fading involves transmitting redundant Turbo-coded packets with new parity bits when an error occurs during decoding of the original packet at the receiver. Turbo-coding in communications systems involves coding/decoding information in stages in order to avoid retransmission of a full L-bit packet upon occurrence of a packet error. In addition to a set of code bits generated by an encoder using a Turbo-coding scheme, a punctured set of code bits is typically generated and stored in transmitter memory. The original set of code bits is transmitted as an L-bit data packet to a receiver, which stores received data samples corresponding to the original set of code bits. The receiver decodes the data packet using a Turbo-decoder and determines whether an error occurred in decoding the received data packet. If so, the received data samples are maintained in memory, and a request for more information is made. Some or all of the punctured information is then forwarded from the transmitter to the receiver. A second stage of Turbo-decoding combines the new data samples with the stored original received data samples such that there is a high likelihood that decoding is correct at this point, but additional stages of decoding may be used. This example of Turbo-coding is generally known and referred to as incremental redundancy. Turbo-coding and the Turbo principle may be applied in additional applications and for other uses, as known to one of ordinary skill in the art.

Many signal processing challenges in communications and other fields can be efficiently solved by using the Turbo principle. According to this principle, the problem is split into two or more separate parts, each of which may be effectively carried out by individual components. So-called extrinsic information is then exchanged between the components representing the computed marginal densities, giving rise to an approximation of the overall joint problem. Applications of this principle include, for example, Turbo equalization for separate detection and decoding and the decoding of Turbo-like codes.

General reference with respect to Turbo codes and the encoding and decoding of Turbo codes may be made to commonly-assigned U.S. Pat. Nos. 6,621,871 to Ross et al.; 6,732,327 to Heinila; 6,771,705 to Kenney et al.; and 6,889,353 to Nieminen. General reference with respect to Turbo equalization may be made to commonly-assigned U.S. Pat. No. 6,996,194 to Pukkila et al.

### SUMMARY

In an exemplary aspect of the invention, a method includes: receiving an encoded signal; and decoding the received signal using a generalized Turbo principle wherein region beliefs are exchanged between components.

In another exemplary aspect of the invention, a program storage device readable by a machine, tangibly embodying a program of instructions executable by the machine for performing operations, said operations including: receiving an encoded signal; and decoding the received signal using a generalized Turbo principle wherein region beliefs are exchanged between components.

In another exemplary aspect of the invention, an apparatus includes: means for receiving an encoded signal; and means for decoding the received signal using a generalized Turbo principle wherein region beliefs are exchanged between components.

In another exemplary aspect of the invention, an apparatus includes: a receiver configured to receive an encoded signal; and a decoder configured to decode the received signal using a generalized Turbo principle wherein region beliefs are exchanged between components.

In another exemplary aspect of the invention, a method for generating a graph structure for a system having a plurality of components includes: defining a set of primary regions, each primary region comprising one observation and a corresponding set of variables required for conditional independence of the observation; and defining a set of secondary regions describing intersections between two primary regions, wherein said intersections are in accordance with a component structure of the plurality of components, wherein each component specifies a subset of the set of secondary regions, wherein the set of primary regions and the set of secondary regions comprise the generated graph structure.

In another exemplary aspect of the invention, a program storage device readable by a machine, tangibly embodying a program of instructions executable by the machine for performing operations for generating a graph structure for a system having a plurality of components, said operations including: defining a set of primary regions, each primary region comprising one observation and a corresponding set of variables required for conditional independence of the observation; and defining a set of secondary regions describing intersections between two primary regions, wherein said intersections are in accordance with a component structure of the plurality of components, wherein each component specifies a subset of the set of secondary regions, wherein the set of primary regions and the set of secondary regions comprise the generated graph structure.

In another exemplary aspect of the invention, an apparatus includes: means for defining a set of primary regions, each primary region comprising one observation and a corresponding set of variables required for conditional independence of the observation; and means for defining a set of secondary regions describing intersections between two primary regions, wherein said intersections are in accordance with a component structure of a plurality of components of a system, wherein each component specifies a subset of the set of secondary regions, wherein the set of first regions and the set of second regions comprise a generated graph structure.

In another exemplary aspect of the invention, an apparatus includes: a processor configured to define a set of primary regions and to define a set of secondary regions describing intersections between two primary regions, wherein the set of first regions and the set of second regions comprise a generated graph structure; and a memory configured to store the generated graph structure, wherein each primary region comprises one observation and a corresponding set of variables required for conditional independence of the observation, wherein said intersections are in accordance with a component structure of a plurality of components of a system.

### BRIEF DESCRIPTION OF THE DRAWINGS

The foregoing and other aspects of exemplary embodiments of this invention are made more evident in the following Detailed Description, when read in conjunction with the attached Drawing Figures, wherein:

FIG. 1 shows a simplified block diagram of various electronic devices that are suitable for use in practicing the exemplary embodiments of this invention;

FIG. 2A shows an exemplary wireless system model that may be utilized in conjunction with various aspects of the exemplary embodiments of the invention;

FIG. 2B depicts an exemplary factor graph representing the exemplary distribution factorization of equation (2.13);

FIG. 2C illustrates an example of region definition for an exemplary factor graph;

FIG. 2D shows an exemplary region graph;

FIG. 2E depicts an exemplary structure for disjoint detection and decoding;

FIG. 2F illustrates an exemplary structure for Turbo-based detection and decoding;

FIG. 2G shows an exemplary factor graph for the Markov model;

FIG. 3A illustrates an exemplary region graph found by the cluster variation method for a convolutionally coded signal over a multipath channel;

FIG. 3B shows an example of a loopy region graph generated by the modified cluster variation method;

FIG. 3C depicts a comparison of LLRs for the modified cluster variation method and Turbo equalization with an exemplary signal;

FIG. 3D illustrates an example of the underlying graph structure of Turbo equalization;

FIG. 3E depicts an exemplary region graph structure for generalized Turbo equalization in accordance with the exemplary embodiments of the invention;

FIG. 3F shows a comparison of traditional and generalized Turbo equalization for an exemplary signal;

FIG. 4 depicts a flowchart illustrating one non-limiting example of a method for practicing the exemplary embodiments of this invention;

FIG. 5 depicts a flowchart illustrating another non-limiting example of a method for practicing the exemplary embodiments of this invention;

FIG. 6 depicts a flowchart illustrating another non-limiting example of a method for practicing the exemplary embodiments of this invention; and

FIG. 7 depicts a flowchart illustrating another non-limiting example of a method for practicing the exemplary embodiments of this invention.

### DETAILED DESCRIPTION

The Turbo principle can be shown to be asymptotically optimal. That is, as the system size (i.e. interleaver length) goes to infinity, the exact marginals can be recovered as the graph approaches a tree. However, for finite systems, such a scheme will be an approximation. The exemplary embodiments of the invention generalize this principle by capturing more of the dependency between components and hence providing a better approximation for such finite systems.

One problem with the traditional Turbo principle is that dependencies between components are not correctly accounted for and, as a result of this, performance may be sub-optimal or the design may even fail to converge. This is especially a problem in smaller systems as powerful couplings are generally disregarded. This phenomenon is a significant reason why, for example, Turbo codes have not been deployed for systems with a “short” frame length. The generalized Turbo principle, as disclosed and further explained in conjunction with the exemplary embodiments of this invention, helps in such situations as a larger portion of the dependencies may be accounted for.

The exemplary embodiments of the invention generalize the traditional Turbo principle by exchanging vector-valued extrinsic information instead of scalar-valued extrinsic information as in the ordinary Turbo principle at the intersection points of the components. Another way of looking at the problem is from the underlying graph point-of-view: The traditional Turbo principle results in a graph where only scalar beliefs of the variables are exchanged at the intersection points of the components. In accordance with the exemplary embodiments of the invention, variables are grouped into regions and it is the beliefs of the regions that are exchanged at the intersection points of the components instead. Effectively, this boils down to performing so-called Generalized Belief Propagation (GBP) on a region graph, where the exchange of information is handled not by scalar-valued beliefs but by entire region beliefs.

One exemplary embodiment operates in a manner somewhat similar to the traditional Turbo principle, however the components are modified to accept region beliefs instead of single variable beliefs in the form of extrinsic information, as explained in further detail below.

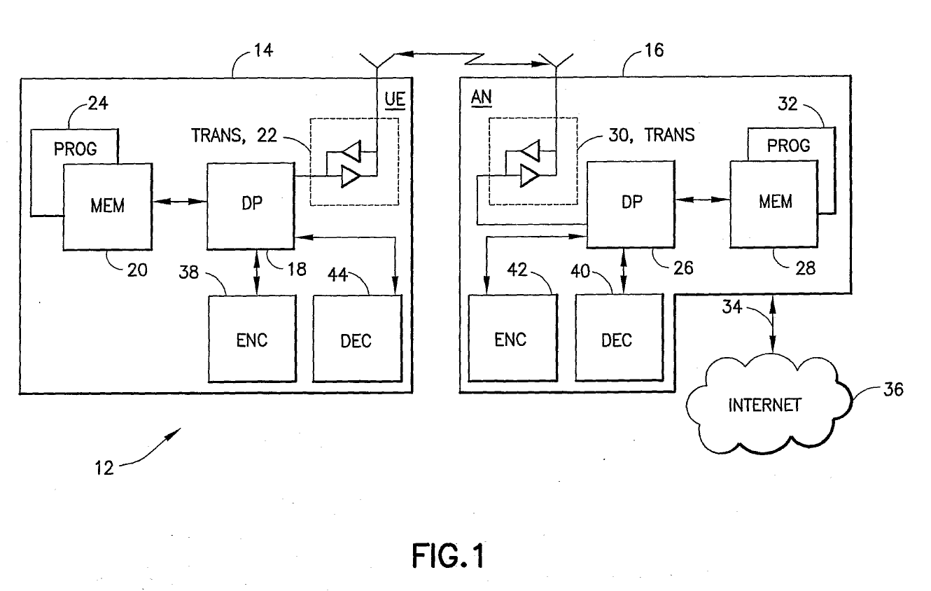

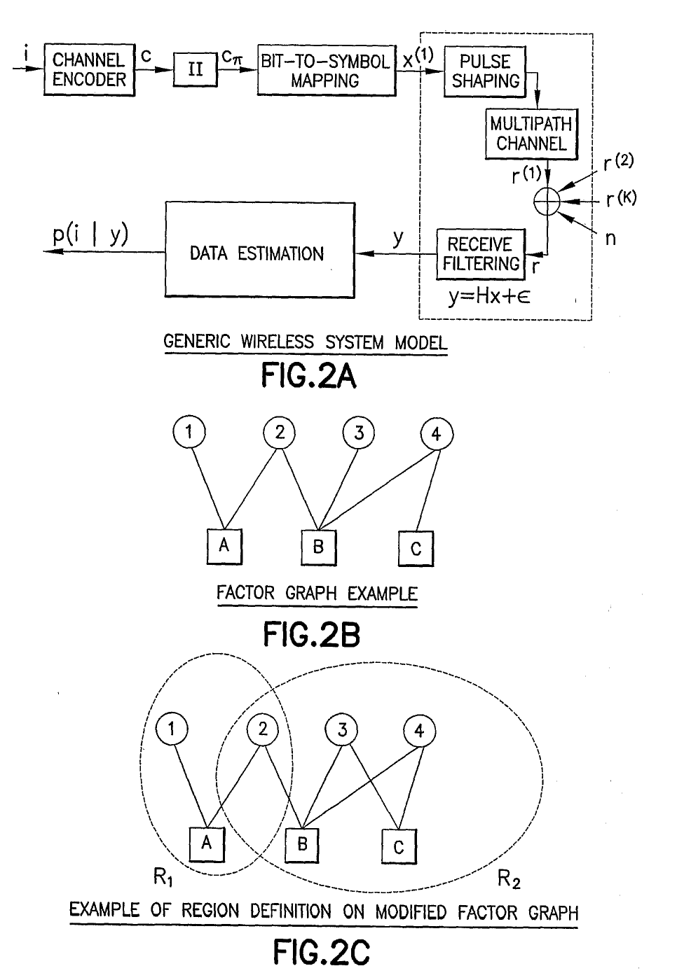

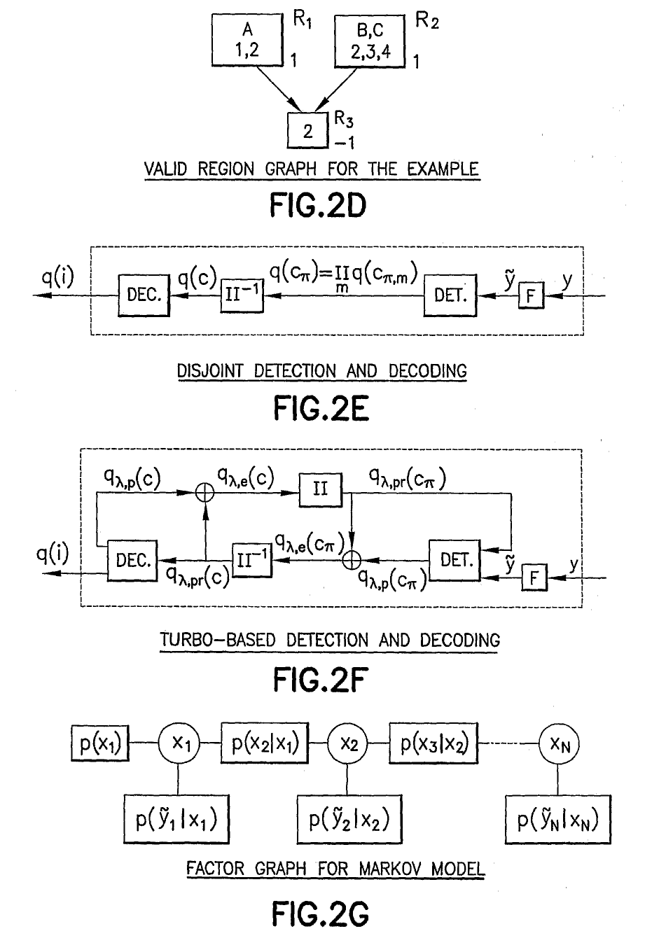

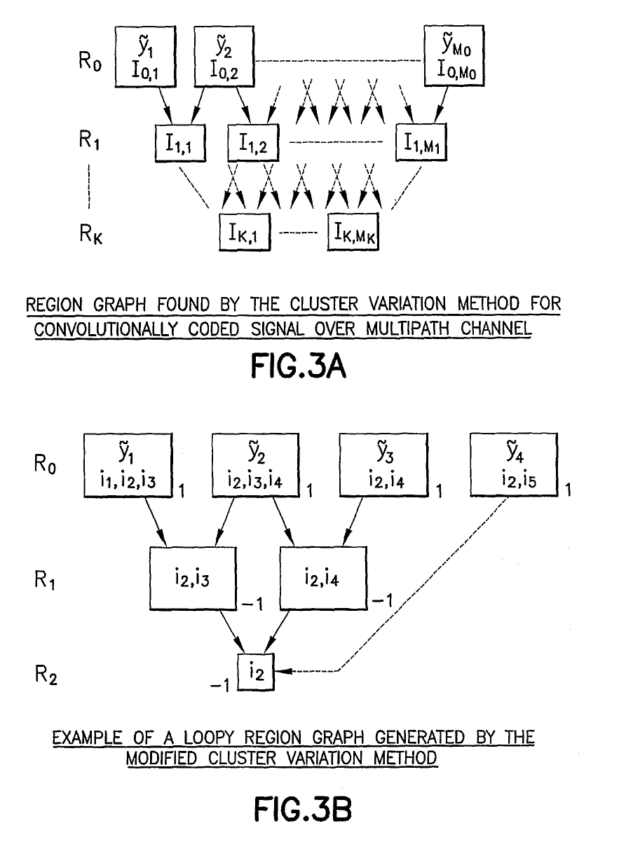

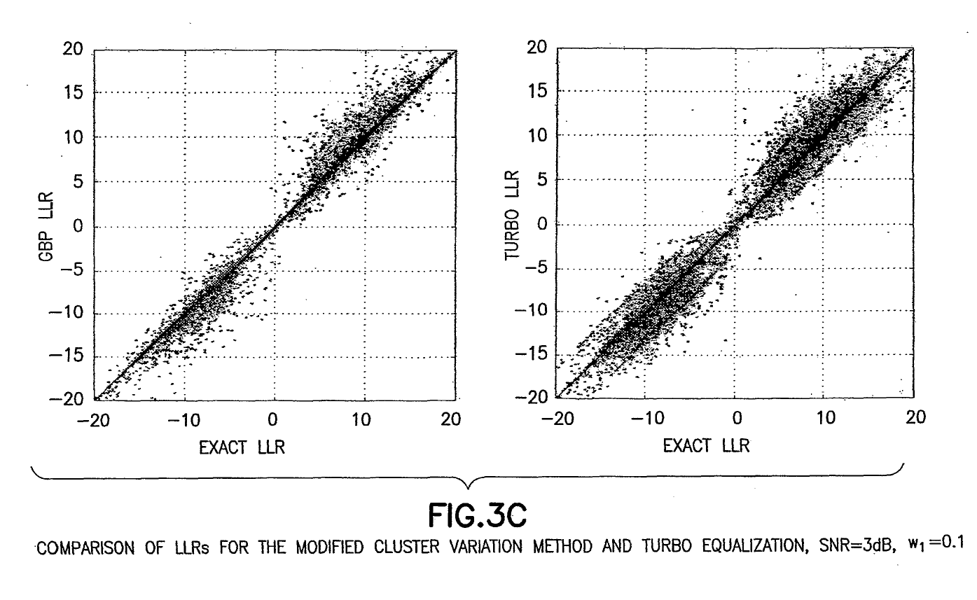

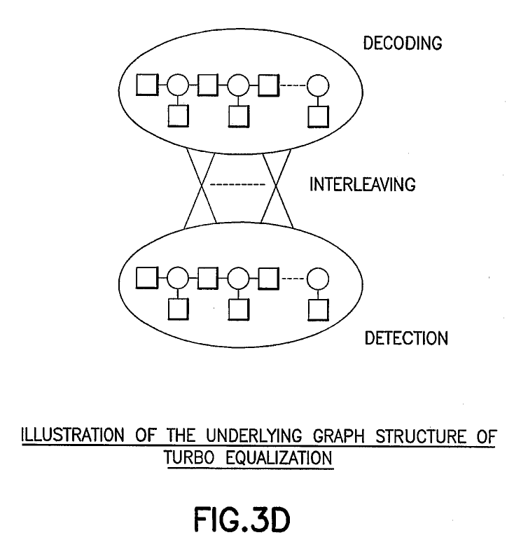

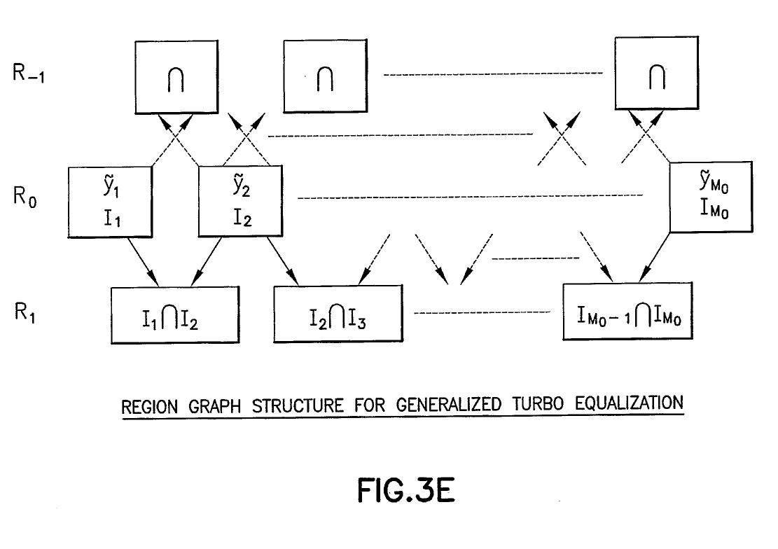

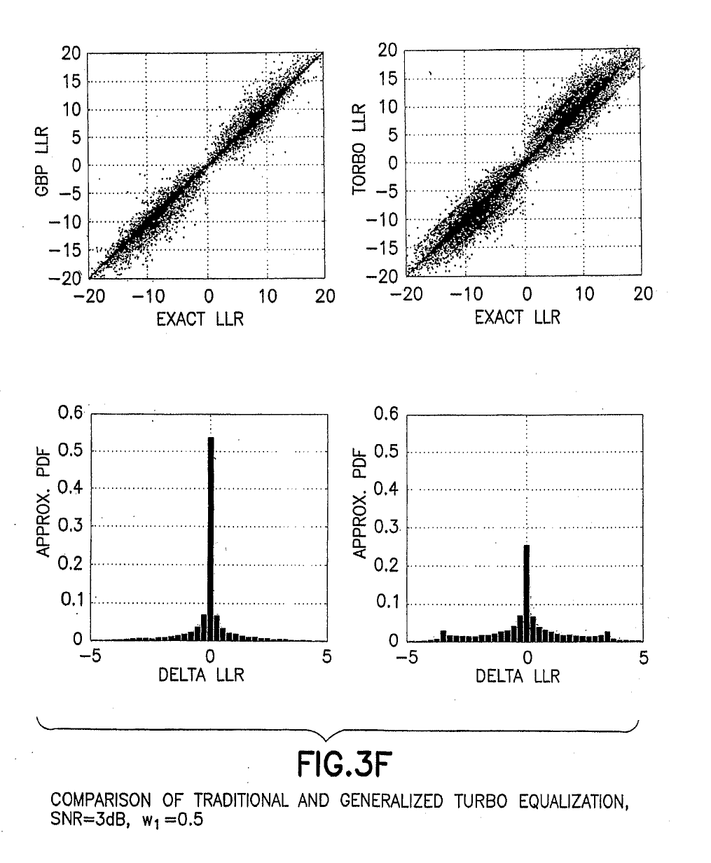

Reference is made to FIG. 1 for illustrating a simplified block diagram of various electronic devices that are suitable for use in practicing the exemplary embodiments of this invention. In FIG. 1, a wireless network 12 is adapted for communication with a user equipment (UE) 14 via an access node (AN) 16. The UE 14 includes a data processor (DP) 18, a memory (MEM) 20 coupled to the DP 18, and a suitable RF transceiver (TRANS) 22 (having a transmitter (TX) and a receiver (RX)) coupled to the DP 18. The MEM 20 stores a program (PROG) 24. The TRANS 22 is for bidirectional wireless communications with the AN 16. Note that the TRANS 22 has at least one antenna to facilitate communication. The UE 14 further includes an encoder (ENC) 38 coupled to the DP 18. The ENC 38 is configured to encode a signal that is to be transmitted by the TRANS 22.

The AN 16 includes a data processor (DP) 26, a memory (MEM) 28 coupled to the DP 26, and a suitable RF transceiver (TRANS) 30 (having a transmitter (TX) and a receiver (RX)) coupled to the DP 26. The MEM 28 stores a program (PROG) 32. The TRANS 30 is for bidirectional wireless communications with the UE 14. Note that the TRANS 30 has at least one antenna to facilitate communication. The AN 16 is coupled via a data path 34 to one or more external networks or systems, such as the internet 36, for example. The AN 16 further includes a decoder (DEC) 40 coupled to the DP 26. The DEC 40 is configured to decode a signal that is received by the TRANS 30.

At least one of the PROGs 24, 32 is assumed to include program instructions that, when executed by the associated DP, enable the electronic device to operate in accordance with the exemplary embodiments of this invention, as discussed herein.

In general, the various embodiments of the UE 14 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The embodiments of this invention may be implemented by computer software executable by one or more of the DPs 18, 26 of the UE 14 and the AN 16, or by hardware, or by a combination of software and hardware.

The MEMs 20, 28 may be of any type suitable to the local technical environment and may be implemented using any suitable data storage technology, such as semiconductor-based memory devices, magnetic memory devices and systems, optical memory devices and systems, fixed memory and removable memory, as non-limiting examples. The DPs 18, 26 may be of any type suitable to the local technical environment, and may include one or more of general purpose computers, special purpose computers, microprocessors, digital signal processors (DSPs) and processors based on a multi-core processor architecture, as non-limiting examples.

The ENC 38 and/or the DEC 40 may comprise one or more of the following: a specialized circuit, an application-specific integrated circuit (ASIC), an integrated circuit, a separate module, a function implemented by the associated DP 18, 26, a function resident in or stored by the associated DP 18, 26 (e.g., in local memory or a local storage structure), and a computer program (PROG) 24, 32 stored in the associated memory (MEM) 20, 28.

Although FIG. 1 depicts the UE 14 as having an ENC 38 and the AN 16 as having a DEC 40, in other exemplary embodiments it is the UE 14 that has a decoder (DEC) 44 and the AN 16 has an encoder (ENC) 42. That is, in such exemplary embodiments the AN 16 is configured to encode a signal and transmit the encoded signal (via TRANS 30) to the UE 14, while the UE 14 is configured to receive the encoded signal (via TRANS 22) and decode it. In further exemplary embodiments, the UE 14 and/or the AN 16 may have both an encoder and a decoder. FIG. 1 illustrates this exemplary embodiment since the AN 16 has both the ENC 42 and the DEC 40 and the UE 14 has both the ENC 38 and the DEC 44. In such exemplary embodiments, the UE 14 and/or the AN 16 are configured to both encode signals and transmit the encoded signals and to receive encoded signals and decode them.

Although FIG. 1 illustrates a wireless communication network 12, the exemplary embodiments of the invention may also be utilized in conjunction with a wired communication network. In such exemplary embodiments, the various embodiments of the UE 14 can include, but are not limited to, desktop computers having communication capabilities, gaming devices having communication capabilities, music storage and playback appliances having communication capabilities, Internet appliances permitting Internet access and browsing, as well as units or terminals that incorporate combinations of such functions.

The exemplary embodiments of the invention generalize the Turbo principle by exchanging vector-valued information or region beliefs between components. This has the advantage of providing a better result, for example, in the form of a lower Bit Error Rate (BER) and better quality of the end-result marginals. In addition, the new framework allows a greater design flexibility than with the traditional Turbo principle. For example, new approximations may be constructed which are in between traditional Turbo and full exhaustive search. While such systems may incur increased complexity, the amount of such an increase largely depends on the approximation made, that is, the underlying graph structure.

While the exemplary embodiments of the invention are particularly suitable for use in a receiver, further exemplary embodiments are also suitable for use in a transmitter wherein the transmitted signal is constructed such that a (generalized) Turbo principle may be utilized by a receiver that receives the signal.

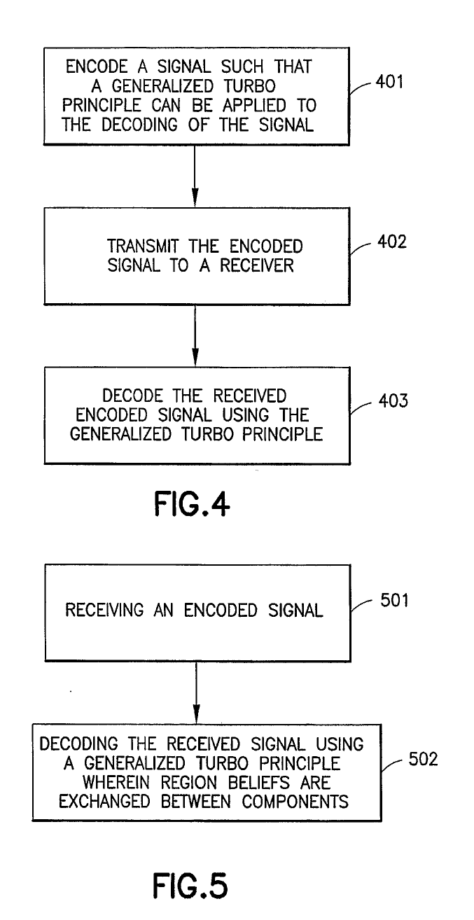

FIG. 4 depicts a flowchart illustrating one non-limiting example of a method for practicing the exemplary embodiments of this invention. The method provides improved signal quality for a transmitted signal. In box 401, a signal is encoded such that a generalized Turbo principle, that is a feature of the exemplary embodiments of this invention, can be applied to the decoding of the signal. In box 402, the encoded signal is transmitted to a receiver. In box 403, the received encoded signal is decoded using the generalized Turbo principle.

In accordance with aspects of the exemplary embodiments of the invention, apparatus, methods and computer program products are provided that utilize a generalized Turbo principle by exchanging region beliefs. In addition, the generalized Turbo principle may be employed in conjunction with Turbo equalization for separate detection and decoding of signals and the encoding or decoding of Turbo-like codes or Turbo-encoded signals. Note that the exchanged region beliefs may be viewed as vector-valued extrinsic information.

In accordance with aspects of the exemplary embodiments of the invention, apparatus, methods and computer program products are provided that utilize a generalized Turbo principle in accordance with a graph where variables are grouped into regions and the beliefs of the regions are exchanged. In further embodiments, Generalized Belief Propagation (GBP) is performed on the region graph.

In accordance with aspects of the exemplary embodiments of the invention, apparatuses, methods and computer program products are provided that afford an improved signal quality (e.g., BER) by: turbo-encoding a signal in accordance with a generalized Turbo principle; transmitting the signal to a receiver; and decoding the turbo-encoded signal.

In accordance with aspects of the exemplary embodiments of the invention, apparatus, methods and computer program products are provided that utilize a generalized Turbo principle in conjunction with the traditional Turbo principle to afford an improved signal quality (e.g., BER).

It is further noted that exemplary embodiments of the invention may also be utilized in conjunction with other applications, such as magnetic storage, for example. An exemplary magnetic storage application would be implemented very similar to the Turbo equalization for communication systems. In this application, there is an error correcting code and a dispersive channel and iterations are here performed between a detector for the channel and a decoder for the code.

Additional possible uses of the invention include demodulation of bit interleaved coded modulation and multi-user and/or multi-stream detection in coded systems. Furthermore, the principle may also be employed in the estimation of various parameters of the system such as channel coefficients, noise covariances, timing and frequency offsets and for initial synchronization, as non-limiting examples. Furthermore, the generalized Turbo principle may also be employed for joint source-channel decoding, where the structure imposed by a source encoder is included in the decoding process. Examples of such source encoders include speech, audio and video encoders, as non-limiting examples. In all of the above cases, the generalized Turbo principle may provide improved performance over that of the traditional Turbo principle by improving the quality of the set marginals as specified by the regions in the graph.

Below are provided further descriptions of non-limiting, exemplary embodiments. The below-described exemplary embodiments are separately numbered for clarity and identification. This numbering should not be construed as wholly separating the below descriptions since various aspects of one or more exemplary embodiments may be practiced in conjunction with one or more other aspects or exemplary embodiments.

(1) In another exemplary embodiment, and as shown in FIG. 5, a method comprising: receiving an encoded signal (501); and decoding the received signal using a generalized Turbo principle wherein region beliefs are exchanged between components (502).

A method as above, wherein the components comprise elements of a structure representing at least one of a code, a communication channel, users in a multi-user system and other components for which a traditional Turbo principle may be employed. A method as in any above, wherein the components may be represented by Markov random fields. A method as in any above, wherein the components comprise at least two Markov chains. A method as in any above, wherein one of the at least two Markov chains corresponds to a convolutive communication channel and another of the at least two Markov chains corresponds to a convolutional code. A method as in any above, wherein at least two Markov chains correspond to a Turbo-like code. A method as in any above, wherein the method is utilized by a wireless communication system. A method as in any above, wherein the method is implemented by a computer program.

(2) In another exemplary embodiment, a program storage device readable by a machine, tangibly embodying a program of instructions executable by the machine for performing operations, said operations comprising: receiving an encoded signal (501); and decoding the received signal using a generalized Turbo principle wherein region beliefs are exchanged between components (502).

A program storage device as above, wherein the components comprise elements of a structure representing at least one of a code, a communication channel, users in a multi-user system and other components for which a traditional Turbo principle may be employed. A program storage device as in any above, wherein the components may be represented by Markov random fields. A program storage device as in any above, wherein the components comprise at least two Markov chains. A program storage device as in any above, wherein one of the at least two Markov chains corresponds to a convolutive communication channel and another of the at least two Markov chains corresponds to a convolutional code. A program storage device as in any above, wherein at least two Markov chains correspond to a Turbo-like code. A program storage device as in any above, wherein the program storage device comprises an element of a wireless communication system.

(3) In another exemplary embodiment, an apparatus (14) comprising: means for receiving (22) an encoded signal; and means for decoding (44) the received signal using a generalized Turbo principle wherein region beliefs are exchanged between components.

An apparatus as above, wherein the components comprise elements of a structure representing at least one of a code, a communication channel, users in a multi-user system and other components for which a traditional Turbo principle may be employed. An apparatus as in any above, wherein the components may be represented by Markov random fields. An apparatus as in any above, wherein the components comprise at least two Markov chains. An apparatus as in any above, wherein one of the at least two Markov chains corresponds to a convolutive communication channel and another of the at least two Markov chains corresponds to a convolutional code. An apparatus as in any above, wherein at least two Markov chains correspond to a Turbo-like code.

An apparatus as in any above, wherein the apparatus comprises an element of a wireless communication system (12). An apparatus as in any above, wherein the means for receiving comprises a receiver and the means for decoding comprises a decoder. An apparatus as in any above, further comprising: means for encoding (38) a signal utilizing the generalized Turbo principle, and means for transmitting (22) the encoded signal. An apparatus as in any above, wherein the means for encoding comprises an encoder and the means for transmitting comprises a transmitter. An apparatus as in any above, further comprising means for processing (18). An apparatus as in any above, further comprising a data processor (18). An apparatus as in any above, further comprising means for storing (20) a computer program (24). An apparatus as in any above, further comprising: a memory (20) configured to store a computer program (24). An apparatus as in any above, wherein the apparatus comprises a terminal, a mobile node, a mobile phone, a cellular phone, a base station or a relay node.

(4) In another exemplary embodiment, an apparatus (14) comprising: a receiver (22) configured to receive an encoded signal; and a decoder (44) configured to decode the received signal using a generalized Turbo principle wherein region beliefs are exchanged between components.

An apparatus as above, wherein the components comprise elements of a structure representing at least one of a code, a communication channel, users in a multi-user system and other components for which a traditional Turbo principle may be employed. An apparatus as in any above, wherein the components may be represented by Markov random fields. An apparatus as in any above, wherein the components comprise at least two Markov chains. An apparatus as in any above, wherein one of the at least two Markov chains corresponds to a convolutive communication channel and another of the at least two Markov chains corresponds to a convolutional code. An apparatus as in any above, wherein at least two Markov chains correspond to a Turbo-like code.

An apparatus as in any above, wherein the apparatus comprises an element of a wireless communication system (12). An apparatus as in any above, wherein the apparatus comprises a terminal, a mobile node, a mobile phone, a cellular phone, a base station or a relay node. An apparatus as in any above, further comprising: an encoder (38) configured to encode a signal utilizing the generalized Turbo principle, and a transmitter (22) configured to transmit the encoded signal. An apparatus as in any above, further comprising a data processor (18). An apparatus as in any above, further comprising: a memory (20) configured to store a computer program (24).

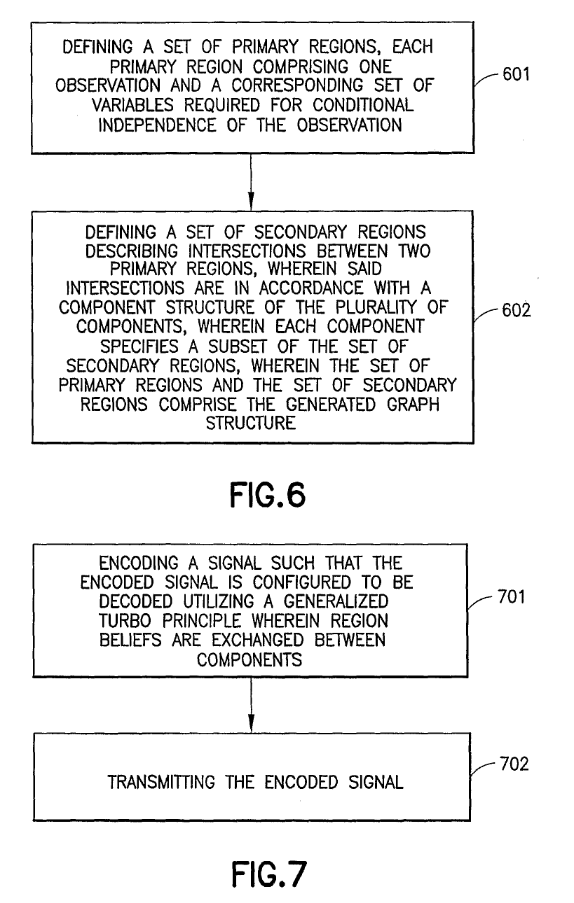

(5) In another exemplary embodiment, and as shown in FIG. 6, a method for generating a graph structure for a system having a plurality of components, comprising: defining a set of primary regions, each primary region comprising one observation and a corresponding set of variables required for conditional independence of the observation; and defining a set of secondary regions describing intersections between two primary regions, wherein said intersections are in accordance with a component structure of the plurality of components, wherein each component specifies a subset of the set of secondary regions, wherein the set of primary regions and the set of secondary regions comprise the generated graph structure.

A method as above, wherein the generated graph structure is representative of at least two intersecting Markov chains, wherein the set of secondary regions describes intersections between primary regions in accordance with the at least two Markov chains, wherein each Markov chain specifies a subset of the set of secondary regions. A method as in any above, further comprising: optimizing the generated graph structure by performing at least one of direct loop removal, merging and enlarging regions in order to minimize loop feedback while balancing an increase in complexity with at least one performance requirement, wherein said optimizing utilizes said intersections or at least one subset of said intersections. A method as in any above, further comprising: performing generalized belief propagation on the generated graph structure, wherein an exchange of information is handled by an exchange of region beliefs. A method as in any above, further comprising: utilizing the generated graph structure to decode a signal. A method as in any above, wherein the method is utilized by a wireless communication system. A method as in any above, wherein the method is implemented by a computer program. A method as in any above, wherein the set of variables comprises variables corresponding to at least one of: symbols, coded bits and information bits.

(6) In another exemplary aspect of the invention, a program storage device readable by a machine, tangibly embodying a program of instructions executable by the machine for performing operations for generating a graph structure for a system having a plurality of components, said operations comprising: defining a set of primary regions, each primary region comprising one observation and a corresponding set of variables required for conditional independence of the observation; and defining a set of secondary regions describing intersections between two primary regions, wherein said intersections are in accordance with a component structure of the plurality of components, wherein each component specifies a subset of the set of secondary regions, wherein the set of primary regions and the set of secondary regions comprise the generated graph structure.

A program storage device as above, wherein the generated graph structure is representative of at least two intersecting Markov chains, wherein the set of secondary regions describes intersections between primary regions in accordance with the at least two Markov chains, wherein each Markov chain specifies a subset of the set of secondary regions. A program storage device as in any above, said operations further comprising: optimizing the generated graph structure by performing at least one of direct loop removal, merging and enlarging regions in order to minimize loop feedback while balancing an increase in complexity with at least one performance requirement, wherein said optimizing utilizes said intersections or at least one subset of said intersections. A program storage device as in any above, the operations further comprising: performing generalized belief propagation on the generated graph structure, wherein an exchange of information is handled by an exchange of region beliefs. A program storage device as in any above, the operations further comprising: utilizing the generated graph structure to decode a signal. A program storage device as in any above, wherein the program storage device comprises an element of a wireless communication system. A program storage device as in any above, wherein the set of variables comprises variables corresponding to at least one of: symbols, coded bits and information bits.

(7) In another exemplary embodiment of the invention, an apparatus comprising: means for defining a set of primary regions, each primary region comprising one observation and a corresponding set of variables required for conditional independence of the observation; and means for defining a set of secondary regions describing intersections between two primary regions, wherein said intersections are in accordance with a component structure of a plurality of components of a system, wherein each component specifies a subset of the set of secondary regions, wherein the set of first regions and the set of second regions comprise a generated graph structure.

An apparatus as above, wherein the generated graph structure is representative of at least two intersecting Markov chains, wherein the set of secondary regions describes intersections between primary regions in accordance with the at least two Markov chains, wherein each Markov chain specifies a subset of the set of secondary regions. An apparatus as in any above, further comprising: means for optimizing the generated graph structure by performing at least one of direct loop removal, merging and enlarging regions in order to minimize loop feedback while balancing an increase in complexity with at least one performance requirement, wherein said means for optimizing utilizes said intersections or at least one subset of said intersections. An apparatus as in any above, wherein the means for optimizing comprises a processor.

An apparatus as in any above, further comprising: means for performing generalized belief propagation on the generated graph structure, wherein an exchange of information is handled by an exchange of region beliefs. An apparatus as in any above, wherein the means for performing generalized belief propagation comprises a processor. An apparatus as in any above, further comprising: means for decoding a signal utilizing the generated graph structure. An apparatus as in any above, wherein the means for decoding comprises a decoder. An apparatus as in any above, wherein the apparatus comprises an element of a wireless communication system. An apparatus as in any above, further comprising: means for storing the generated graph structure. An apparatus as in any above, wherein the means for storing comprises a memory. An apparatus as in any above, wherein the apparatus comprises: a terminal, a user equipment, a mobile device, a mobile phone, a network equipment or a base station. An apparatus as in any above, wherein the means for defining a set of primary regions and the means for defining a set of secondary regions comprise a processor. An apparatus as in any above, wherein the set of variables comprises variables corresponding to at least one of: symbols, coded bits and information bits.

(8) In another exemplary embodiment of the invention, an apparatus comprising: a processor configured to define a set of primary regions and to define a set of secondary regions describing intersections between two primary regions, wherein the set of first regions and the set of second regions comprise a generated graph structure; and a memory configured to store the generated graph structure, wherein each primary region comprises one observation and a corresponding set of variables required for conditional independence of the observation, wherein said intersections are in accordance with a component structure of a plurality of components of a system.

An apparatus as above, wherein the generated graph structure is representative of at least two intersecting Markov chains, wherein the set of secondary regions describes intersections between primary regions in accordance with the at least two Markov chains, wherein each Markov chain specifies a subset of the set of secondary regions. An apparatus as in any above, wherein the processor is further configured to optimize the generated graph structure by performing at least one of direct loop removal, merging and enlarging regions in order to minimize loop feedback while balancing an increase in complexity with at least one performance requirement, wherein said optimizing utilizes said intersections or at least one subset of said intersections.

An apparatus as in any above, wherein the processor is further configured to perform generalized belief propagation on the generated graph structure, wherein an exchange of information is handled by an exchange of region beliefs. An apparatus as in any above, further comprising: a decoder configured to decode a signal utilizing the generated graph structure. An apparatus as in any above, wherein the apparatus comprises an element of a wireless communication system. An apparatus as in any above, wherein the apparatus comprises: a terminal, a user equipment, a mobile device, a mobile phone, a network equipment or a base station. An apparatus as in any above, wherein the set of variables comprises variables corresponding to at least one of symbols, coded bits and information bits.

(9) In another exemplary embodiment, and as shown in FIG. 7, a method comprising: encoding a signal such that the encoded signal is configured to be decoded utilizing a generalized Turbo principle wherein region beliefs are exchanged between components (701); and transmitting the encoded signal (702).

A method as above, wherein the components comprise elements of a structure representing at least one of a code, a communication channel, users in a multi-user system and other components for which a traditional Turbo principle may be employed. A method as in any above, wherein the components may be represented by Markov random fields. A method as in any above, wherein the components comprise at least two Markov chains. A method as in any above, wherein one of the at least two Markov chains corresponds to a convolutive communication channel and another of the at least two Markov chains corresponds to a convolutional code. A method as in any above, wherein at least two Markov chains correspond to a Turbo-like code. A method as in any above, wherein the method is utilized by a wireless communication system. A method as in any above, wherein the method is implemented by a computer program.

(10) In another exemplary embodiment, a program storage device readable by a machine, tangibly embodying a program of instructions executable by the machine for performing operations, said operations comprising: encoding a signal such that the encoded signal is configured to be decoded utilizing a generalized Turbo principle wherein region beliefs are exchanged between components; and transmitting the encoded signal.

A program storage device as above, wherein the components comprise elements of a structure representing at least one of a code, a communication channel, users in a multi-user system and other components for which a traditional Turbo principle may be employed. A program storage device as in any above, wherein the components may be represented by Markov random fields. A program storage device as in any above, wherein the components comprise at least two Markov chains. A program storage device as in any above, wherein one of the at least two Markov chains corresponds to a convolutive communication channel and another of the at least two Markov chains corresponds to a convolutional code. A program storage device as in any above, wherein at least two Markov chains correspond to a Turbo-like code. A program storage device as in any above, wherein the program storage device comprises an element of a wireless communication system.

(11) In another exemplary embodiment, an apparatus comprising: means for encoding a signal such that the encoded signal is configured to be decoded utilizing a generalized Turbo principle wherein region beliefs are exchanged between components; and means for transmitting the encoded signal.

An apparatus as above, wherein the components comprise elements of a structure representing at least one of a code, a communication channel, users in a multi-user system and other components for which a traditional Turbo principle may be employed. An apparatus as in any above, wherein the components may be represented by Markov random fields. An apparatus as in any above, wherein the components comprise at least two Markov chains. An apparatus as in any above, wherein one of the at least two Markov chains corresponds to a convolutive communication channel and another of the at least two Markov chains corresponds to a convolutional code. An apparatus as in any above, wherein at least two Markov chains correspond to a Turbo-like code. An apparatus as in any above, wherein the apparatus comprises an element of a wireless communication system. An apparatus as in any above, wherein the means for encoding comprises an encoder and the means for transmitting comprises a transmitter. An apparatus as in any above, further comprising: means for receiving a signal and means for decoding the received signal using the generalized Turbo principle. An apparatus as in any above, wherein the means for receiving comprises a receiver and the means for decoding comprises a decoder.

(12) In another exemplary embodiment, an apparatus comprising: an encoder configured to encode a signal such that the encoded signal is configured to be decoded utilizing a generalized Turbo principle wherein region beliefs are exchanged between components; and a transmitter configured to transmit the encoded signal.

An apparatus as above, wherein the components comprise elements of a structure representing at least one of a code, a communication channel, users in a multi-user system and other components for which a traditional Turbo principle may be employed. An apparatus as in any above, wherein the components may be represented by Markov random fields. An apparatus as in any above, wherein the components comprise at least two Markov chains. An apparatus as in any above, wherein one of the at least two Markov chains corresponds to a convolutive communication channel and another of the at least two Markov chains corresponds to a convolutional code. An apparatus as in any above, wherein at least two Markov chains correspond to a Turbo-like code. An apparatus as in any above, wherein the apparatus comprises an element of a wireless communication system. An apparatus as in any above, wherein the apparatus comprises a terminal, a mobile node, a mobile phone, a cellular phone, a base station or a relay node. An apparatus as in any above, further comprising: a receiver configured to receive a signal and a decoder configured to decode the received signal using the generalized Turbo principle.

(13) A system comprising: a first apparatus and a second apparatus, said first apparatus comprising means for encoding a signal utilizing a generalized Turbo principle wherein region beliefs are exchanged between components, and means for transmitting the encoded signal, said second apparatus comprising means for receiving the encoded signal; and means for decoding the received signal using the generalized Turbo principle. A system as above, further comprising one or more aspects of the exemplary embodiments of the invention as further described herein.
(14) A system comprising: a first apparatus and a second apparatus, said first apparatus comprising an encoder configured to encode a signal utilizing a generalized Turbo principle wherein region beliefs are exchanged between components, and a transmitter configured to transmit the encoded signal, said second apparatus comprising a receiver configured to receive the encoded signal; and a decoder configured to decode the received signal using the generalized Turbo principle. A system as above, further comprising one or more aspects of the exemplary embodiments of the invention as further described herein.
(15) A method comprising: encoding a signal utilizing a generalized Turbo principle; and transmitting the encoded signal. A method as above, further comprising one or more aspects of the exemplary embodiments of the invention as further described herein.
(16) A method comprising: receiving an encoded signal; and decoding the received signal using a generalized Turbo principle wherein region beliefs are exchanged between components. A method as above, further comprising one or more aspects of the exemplary embodiments of the invention as further described herein.

It should be appreciated that the exemplary embodiments of the invention, and particularly as related to exemplary methods, may be implemented by a computer program, a computer program product comprising program instructions tangibly embodied on a computer readable medium where execution of the program instructions comprises the steps or elements of the exemplary embodiments of the invention, and/or a program storage device (e.g., a computer readable medium, memory) readable by a machine and tangibly embodying a program of instructions executable by the machine for performing operations comprises the steps or elements of the exemplary embodiments of the invention.

While the exemplary embodiments have been described above in the context of a generalized wireless communication system, it should be appreciated that the exemplary embodiments of this invention are not limited for use with only this one particular type of system, and that they may be used to advantage in other wired and wireless communication systems.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

It should further be noted that any reference to a “traditional Turbo principle” should be construed as referring to a conventional application or use of the Turbo principle.

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The exemplary embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of the non-limiting and exemplary embodiments of this invention.

Furthermore, some of the features of the preferred embodiments of this invention could be used to advantage without the corresponding use of other features. As such, the foregoing description should be considered as merely illustrative of the principles, teachings and exemplary embodiments of this invention, and not in limitation thereof.

1. A method comprising:
receiving an encoded signal and
decoding the received signal using a generalized Turbo principle wherein multivariable beliefs are exchanged between components

2. A method as in claim 1, wherein the components comprise elements of a structure representing at least one of a code, a communication channel, users in a multi-user system and other components for which a traditional Turbo principle may be employed.

3. A method as in claim 1, wherein the components may be represented by Markov random fields.

4. A method as in claim 1, wherein the components comprise at least two Markov chains.

5. A method as in claim 4, wherein one of the at least two Markov chains corresponds to a convolutive communication channel and another of the at least two Markov chains corresponds to a convolutional code.

6. A method as in claim 4, wherein at least two Markov chains correspond to a Turbo-like code.

7-57. (canceled)

58. A method comprising:
defining a set of primary regions, each primary region comprising one observation and a corresponding set of variables required for conditional independence of the observation;
defining a set of secondary regions describing intersections between two primary regions, wherein said intersections are in accordance with a component structure of a plurality of components, wherein each component specifies a subset of the set of secondary regions; and
generating, based on the sets of primary and secondary regions, a graph structure for the plurality of components, wherein the generated graph structure may be used to decode a signal using generalized belief propagation.

59. A method as in claim 58, wherein the generated graph structure is representative of at least two intersecting Markov chains, wherein the set of secondary regions describes intersections between primary regions in accordance with the at least two Markov chains, wherein each Markov chain specifies a subset of the set of secondary regions.

60. A method as in claim 58, further comprising: optimizing the generated graph structure by performing at least one of direct loop removal, merging and enlarging regions in order to minimize loop feedback while balancing an increase in complexity with at least one performance requirement, wherein said optimizing utilizes said intersections or at least one subset of said intersections.

61. A method as in claim 58, further comprising: performing generalized belief propagation on the generated graph structure, wherein an exchange of information is handled by an exchange of region beliefs.

62. A method as in claim 58, further comprising: utilizing the generated graph structure to decode a signal.

63. A method as in claim 58, wherein the method is utilized by a wireless communication system.

64. A method as in claim 58, wherein the method is implemented by a computer program.

65. An apparatus comprising a processor and a memory storing executable instructions that in response to execution by the processor cause the apparatus to at least perform the following:
defining a set of primary regions, each primary region comprising one observation and a corresponding set of variables required for conditional independence of the observation;
defining a set of secondary regions describing intersections between two primary regions, wherein said intersections are in accordance with a component structure of a plurality of components of a system, wherein each component specifies a subset of the set of secondary regions; and
generating, based on the sets of primary and secondary regions, a graph structure for the plurality of components, wherein the generated graph structure may be used to decode a signal using generalized belief propagation.

66. An apparatus as in claim 65, wherein the generated graph structure is representative of at least two intersecting Markov chains, wherein the set of secondary regions describes intersections between primary regions in accordance with the at least two Markov chains, wherein each Markov chain specifies a subset of the set of secondary regions.

67. An apparatus as in claim 65, wherein the processor is further configured to optimize the generated graph structure by performing at least one of direct loop removal, merging and enlarging regions in order to minimize loop feedback while balancing an increase in complexity with at least one performance requirement, wherein said optimizing utilizes said intersections or at least one subset of said intersections.

68. An apparatus as in claim 65, wherein the processor is further configured to perform generalized belief propagation on the generated graph structure, wherein an exchange of information is handled by an exchange of region beliefs.

69. An apparatus as in claim 65, further comprising: a decoder configured to decode a signal utilizing the generated graph structure.

70. An apparatus as in claim 65, wherein the apparatus comprises an element of a wireless communication system.
